(19) United States
(12) Patent Application Publication
(10) Pub. No.: US 2010/0079039 A1
(43) Pub. Date: Apr. 1, 2010

(54) PIEZOELECTRIC ACTUATOR WITH AN IMPROVED STROKE CAPABILITY

(75) Inventors: Stefan Lampenscherf, Poing (DE); Andreas Wolff, Munchen (DE)

Correspondence Address: YOUNG & THOMPSON, 209 Madison Street, Suite 500, Alexandria, VA, 22314, US

(73) Assignee: SIEMENS AKTIENGESELLSCHAFT, Munchen (DE)

(21) Appl. No.: 11/993,462

(22) PCT Filed: Jun. 7, 2006
(86) PCT No.: PCT/EP06/62961

§ 371 Date: Sep. 25, 2008

(30) Foreign Application Priority Data
Jun. 22, 2005 (DE) 10 2005 028 970.3

(51) Int. Cl. H01L 41/04; H01L 41/22

(52) U.S. Cl. 310/367; 29/25.35

(57) ABSTRACT

A piezoelectric actuator (1) with an improved stroke capability, achieved by the utilization of the deformation characteristics of specially structured piezoceramic layers (10) and the simultaneous influence of a mechanical pre-stress and an electric field. A method for producing the piezoelectric actuators (1) is described. The piezoelectric actuators are suitable for a low-voltage operation, for example in the fields of biotechnology and medical technology (micro-pumps, micro-valves), industrial electronics (pneumatic valves) and the fields of micro-actuators and micro-motors.

The present invention relates to piezoelectric actuators, which, when an electric voltage is applied, display a specific expansion response as a function of said electric voltage.

Piezoelectric actuators are used in a very wide range of technologies. They are produced with a multilayer structure for example. These multilayer piezoelectric actuators are used to activate injection valves in internal combustion engines, positioning tables or in electronic device technology, to name a few examples.

U.S. Pat. No. 6,274,967 discloses a piezoelectric actuator with a multilayer structure, which is equipped with a pretensioning device to induce a force in the piezoelectric layers. The pretensioning device is used to apply a single-axial compressive tension to the piezoelectric layers along the stack direction of the piezoelectric actuator.

WO 2004/015789 A2 discloses a piezoelectric actuator with at least one stack-type piezoelectric element. The piezoelectric element surrounded by electrodes is held in a pretensioning device in such a manner that a force is induced in a sub-volume of the piezoelectric layer. The mechanical pretension introduced into the piezoelectric layer combines with an electric field acting in the piezoelectric layer to generate an increased expansion compared with conventional piezoelectric actuator designs. Despite this expansion response or stroke capability of the piezoelectric actuator, different areas of engineering, for example micro-engineering, require a further stroke increase or an improved expansion response from piezoelectric actuators.

The object of the invention is therefore to provide a piezoelectric actuator with an improved stroke response compared with the prior art.

The above object is achieved by a piezoelectric actuator as claimed in the independent claim 1 and a method for its production as claimed in the independent claim 6.

The inventive piezoelectric actuator has the following features: at least one piezoelectric layer with at least one arch, which is disposed between two opposing electrode layers for generating an electric field in the piezoelectric layer, and a pretensioning device, by means of which a mechanical strain in the piezoelectric layer can be set by way of the at least one arch, so that when an electric field is generated in the pretensioned piezoelectric layer, the mechanical strain assists an expansion response on the part of the piezoelectric actuator.

Based on the present invention a stroke increase is achieved in piezoelectric actuators by utilizing the deformation characteristics of specially structured or profiled piezoceramic layers. To this end the piezoelectric layer is provided with at least one arch in contrast to flat piezoelectric layers in multilayer actuators. When the piezoelectric layer has been poled, it is pretensioned mechanically with the aid of a pretensioning device by way of the at least one arch. If the polarized and mechanically pretensioned piezoelectric layer is now charged with an electric field, piezoelectric and ferroelectric expansion components are superimposed within the piezoelectric layer resulting in its deformation and a stroke increase in the piezoelectric actuator compared with known actuators from the prior art.

According to one embodiment the piezoelectric layer of the piezoelectric actuator comprises a plurality of regularly and/or irregularly disposed arches. It is also preferable for the piezoelectric layer of the piezoelectric actuator to have a plurality of identically and/or non-identically formed arches.

Depending on the form, number and arrangement of the arches, the stroke capability of the piezoelectric actuator is improved to a differing degree. Thus for example spheres or truncated cone-type arches are embossed in a regular arrangement in the piezoelectric layer. It is similarly preferable for sinusoidal waveforms extending over the entire width of the piezoelectric layer to be embossed in the piezoelectric layer, in order to improve the stroke capability of the piezoelectric actuator with this periodic structure. The piezoelectric layer then has a form similar to a corrugated metal sheet.

The present invention also discloses a method for producing a piezoelectric actuator having the following steps: casting and drying a film of piezoelectric material on a support film, laying the film of piezoelectric material out on a surface with at least one irregularity to emboss at least one arch into the film, sintering the film on the surface with the at least one irregularity and applying electrodes to the opposing sides of the film and clamping the film in a pretensioning device.

First piezoelectric green films are produced using known methods. These films of piezoelectric material are then laid out on a surface, the irregularities of which emboss specific deformations into said film. These irregularities are formed for example by spheres, truncated cones or bars or elevations extending over the entire width of the surface.

Depending on the desired form and arrangement of the arches in the piezoelectric film, the irregularities are disposed in an irregular and/or regular pattern on the surface. It is also preferable to use a plurality of identically and/or non-identically formed irregularities on the surface.

Preferred embodiments and refinements of the present invention are described in the description which follows with reference to the accompanying drawing and in the attached claims. In the accompanying drawings:

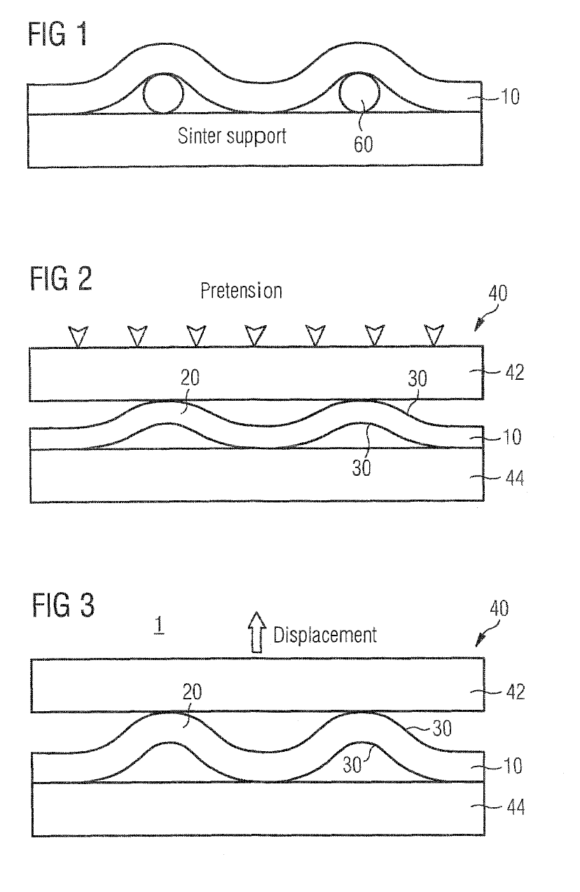

FIG. 1 shows a schematic diagram of the surface of a sinter support with irregularities, on which the film of piezoelectric material is laid out,

FIG. 2 shows a preferred embodiment of the piezoelectric actuator subject to mechanical pretensioning,

FIG. 3 shows a preferred embodiment of the piezoelectric actuator of the present invention subject to the action of an electric field.

The inventive piezoelectric actuator 1 has at least one piezoelectric layer 10, into which at least one arch 20 is embossed (see FIGS. 2 and 3). To apply an electric voltage to the piezoelectric layer 10, electrode layers 30 for generating an electric field in the piezoelectric layer 10 are disposed on its opposing sides. The piezoelectric layer 10, which is irregular or structured due to the arches 20 is mechanically strained with the aid of a pretensioning device 40. The pretensioning device 40 exerts pressure on the at least one arch 20 of the piezoelectric layer 10, thereby straining the piezoelectric layer 10. If an electric field produces an expansion in the piezoelectric layer 10, the superimposition of piezoelectric and ferroelectric expansion components with mechanical strain conditions results in an improved stroke capability in the piezoelectric actuator 1 compared with piezoelectric actuators of the prior art.

The piezoelectric actuator 1 is produced according to the following preferred steps. First a film or green film of piezoelectric material is produced on a support film by casting and drying according to known methods. This film of piezoelectric material formed the piezoelectric layer 10 on completion of the production process.

The film of piezoelectric material is then laid out on a surface 50 with at least one irregularity 60 (see FIG. 1). The surface 50 is preferably formed by the sinter support, on which at least one or a plurality of irregularities 60 is disposed in a specific manner. The film of piezoelectric material is pressed by gravity onto the surface 50 and the irregularities 60 disposed there, so that the irregularities each emboss an arch 20 into the film.

According to different embodiments, the irregularities 60 are disposed in a regular and/or irregular manner on the surface 50. It is also preferable for the irregularities 60 to have identical or non-identical forms. These irregularities 60 for example have the form of a sphere, a hemisphere, a pin, a truncated cone, a square elevation, a bead-type elevation or an elongated finger-type elevation. As described above, the irregularities 60 emboss arches formed and disposed in a complementary or identical manner into the film. This produces a film of piezoelectric material, having regularly and/or irregularly disposed arches 20, which can also have identical and/or non-identical forms.

Based on the diversity of the structuring of the piezoceramic layer 10, it is preferable to use a regular arrangement of bar-type irregularities 60 on the surface 50. These bar-type irregularities 60 extend in a parallel manner and at equal distances from each other over the entire width of the surface 50. When this structure of surface 50 and irregularities 60 is embossed into the piezoceramic layer 10, a periodically wave-type profile results within the piezoceramic layer 10. This is shown schematically in FIG. 3.

Once a specific structure has been introduced into the film of piezoelectric material, said film is sintered on the surface 50 with the at least one irregularity 60. After sintering, electrode layers 30 are applied to the two opposing flat sides of the piezoceramic layer using known methods. These electrode layers 30 are used for the polarization of the piezoelectric layer 10 then taking place. An electric voltage is connected to the electrode layers 30, thereby generating an electric field in the piezoelectric layer 10.

After polarization the structured piezoelectric layer 10 is clamped into the pretensioning device 40, to produce specific pretensions in the piezoceramic layer 10. The pretensioning device 40 consists of a first plate 42, which is disposed above the piezoceramic layer 10, and a second plate 44, which is disposed below the piezoceramic layer 10 (see FIGS. 2 and 3). Moving the two plates 42 and 44 onto each other causes mechanical tensions to be induced in the piezoceramic layer 10 by way of the arches 20. The piezoceramic layer 10 is compressed by the pretensioning device 10.

The method steps described above are used to produce the piezoelectric actuator 10, which demonstrates the desired stroke improvement for piezoelectric actuators 1 using the deformation characteristics of specially structured piezoceramic layers. The structuring of the piezoelectric layer 1 consists of embossing one or more arches 20 according to FIG. 1, so that these are embossed on at least one side over the surface of the piezoceramic layer 10.

In the piezoelectric actuator 1 according to FIG. 3 the mechanical pretensioning of the pretensioning device 40 results in the partial impressing of the arches 20, which are comparable to disk springs. The mechanical pretension introduced is in equilibrium with the elastic expansion distribution in the piezoceramic layer 10. After the electric voltage has been applied to the piezoceramic layer 10 by way of the electrode layers 30, additional piezoelectric and ferroelectric expansion components result. Depending on external mechanical clamping/pretensioning conditions, a different deformation of the at least one arch 20 or the plurality of arches 20 reaches equilibrium as with conventional regular piezoelectric layers of multilayer actuators. The strong non-linear relationship between the expansion state and the height of the layer arch means that a significantly greater stroke change can be achieved for each piezoceramic layer 10 than is possible with the thickness change in the piezoceramic layers utilized in the conventional stack actuator. The specifically introduced arches 20 of the piezoceramic layer 10 therefore represent a transformation mechanism to convert the changes in the expansion state of the piezoceramic layer 10 caused by piezoelectric and/or ferroelectric effects to force and deformation components perpendicular to the layer 10.

By varying the form, size, number and arrangement of the arches 20 and by stacking a number of structure layers 10, it is possible to produce piezoelectric actuators 1 with a large stroke with a wide range of applications. When selecting the preliminary force or mechanical pretension it is also possible to adjust the stroke and rigidity of the piezoelectric actuators 1 described. With a correspondingly high mechanical pretension ferroelastic deformation components may develop (for example due to the flipping over of ferroelectric domains into the layer plane, in other words parallel to the plates 42, 44 of the pretensioning device), which can be switched back again by the electrical activation system. It is also possible to enlarge the expansion amplitude and therefore also the stroke of the piezoelectric actuator 1 in this manner.

The advantage therefore lies in the specific combination of piezoelectric, ferroelectric and ferroelastic effects with the deformation characteristics of layer arches, in order to produce piezoelectric actuators 1 with a significantly larger stroke than conventional stack actuators. The combination of piezoceramic multilayer technology, micro-structuring and micro-engineering permits economical new mass applications for low-voltage operation, for example in the fields of biotechnology and medical engineering (micro-pumps, micro-valves), industrial electronic engineering (pneumatic valves) and micro-actuators and micro-motors, with the method described above.

1. A piezoelectric actuator (1) having the following features:
a. at least one piezoelectric layer (10) with at least one arch (20), which is disposed between two opposing electrode layers (30) for generating an electric field in the piezoelectric layer (10) and
b. a pretensioning device (40), by means of which a mechanical strain in the piezoelectric layer (10) can be set by way of the at least one arch (20) so that when an electric field is generated in the pretensioned piezoelectric layer (10), the mechanical strain assists an expansion response of the piezoelectric actuator (1).

2. The piezoelectric actuator (1) as claimed in claim 1,
whose piezoelectric layer (10) has a plurality of regularly and/or irregularly disposed arches (20).

3. The piezoelectric actuator (1) as claimed in claim 1, having a plurality of identically and/or non-identically formed arches (20).

4. The piezoelectric actuator (1) as claimed in claim 1, whose piezoelectric layer (10) has a periodically wave-type profile.

5. The piezoelectric actuator (1) as claimed in claim 1, whose pretensioning device (40) has a first plate (42) and a second plate (44), with which the at least one arch (20) of the piezoelectric layer (10) can be compressed.

6. A method for producing a piezoelectric actuator (1), having the following steps:
a. casting and drying a film of piezoelectric material on a support film,
b. laying the film of piezoelectric material out on a surface (50) with at least one irregularity (60), to emboss at least one arch (20) into the film,
c. sintering the film on the surface (50) with the at least one irregularity (60) and
d. applying electrodes to the opposing sides of the film and clamping the film in a pretensioning device.

7. The method as claimed in claim 6, also featuring:
arranging a plurality of irregularities (60) on the surface (50) in an irregular and/or a regular pattern.

8. The method as claimed in claim 6, also featuring:
arranging a plurality of identically and/or non-identically formed irregularities (60) on the surface (50).

9. The method as claimed in claim 7, also featuring:
arranging a plurality of identically and/or non-identically formed irregularities (60) on the surface (50).

10. The piezoelectric actuator (1) as claimed in claim 2, having a plurality of identically and/or non-identically formed arches (20).

11. The piezoelectric actuator (1) as claimed in claim 2, whose pretensioning device (40) has a first plate (42) and a second plate (44), with which the at least one arch (20) of the piezoelectric layer (10) can be compressed.

12. The piezoelectric actuator (1) as claimed in claim 3, whose pretensioning device (40) has a first plate (42) and a second plate (44), with which the at least one arch (20) of the piezoelectric layer (10) can be compressed.

13. The piezoelectric actuator (1) as claimed in claim 4, whose pretensioning device (40) has a first plate (42) and a second plate (44), with which the at least one arch (20) of the piezoelectric layer (10) can be compressed.
